(19) United States
(12) Patent Application Publication
(10) Pub. No.: US 2005/0231303 A1
(43) Pub. Date: Oct. 20, 2005

(54) Tunable passive device

(76) Inventors: Chao-Liang Chang, Hsinchu (TW); Chao-Ta Huang, Hsinchu (TW)

Correspondence Address: HARNESS, DICKEY & PIERCE, P.L.C., P.O. BOX 8910, RESTON, VA, 20195, US

(21) Appl. No.: 10/901,024

(22) Filed: Jul. 29, 2004

(30) Foreign Application Priority Data
Apr. 16, 2004 (TW) 93110694

(51) Int. Cl. H03H 7/12

(52) U.S. Cl. 333/174

(57) ABSTRACT

A tunable passive device is disclosed. It includes a plurality of passive elements and at least a switch. The passive elements are stacked along the same direction, and connected with each other via the switch. By changing open/close conditions of the switch(es) and selecting specific passive elements that a current can pass, a responsive value of the tunable passive device is obtained.

### FIELD OF THE INVENTION

The invention generally relates to a passive device, and in particular relates to a tunable passive device.

### BACKGROUND OF THE INVENTION

Capacitors, resistors and inductors are three kinds of major passive devices. Functionally, capacitors store electrical charge and release electrical power in certain time interval; resistors adjust voltage and current in circuits; inductors work as filters, chargers and dischargers. The three ones usually cooperate to achieve electronic control functions. Most electronic and electrical products use the passive devices in the fields of information, communication, consumer electronics and other industries. Passive devices become essential components in 3C industries and are required more and more as electronic technologies and products being developed.

In order to control the quality of electrical circuits, the requirements of qualified passive devices become more important. Especially the passive devices of capacitors and inductors that generate frequency response highly influence the working frequency and power transmission. Some components, such as electronically tunable filters and voltage-controlled oscillators (VCOs), applied in wireless communication or micro-electromechanical systems (especially in energy storage and communication modules of bioelectrical systems) usually work for high frequencies, such as 13.56 MHz. The applications require components of high inductance or high capacitance, which usually have larger dimensions that cannot meet the requirements of system microminiaturization. Therefore, tunable passive devices applicable in aforesaid circuits are required to have higher densities of inductance or capacitance and larger tunable range in order to reduce the space requirement and increase the flexibility of circuit design.

Conventional tunable passive devices are mainly of unitary capacitor or inductor tunable by adjustment of inductive areas for different capacitances or inductances.

For example, a tunable capacitor is tuned by changing the clearance of two electrode plates. However, restrained by a “pull in” effect of electrodes, the tunable range is limited. That is, when the clearance of electrode plates is reduced to one third of an original clearance, the “pull in” effect makes the electrode plate contact to each other. Therefore, a practical minimum space is two third of original clearance, and theoretically allows a tunable range of 50%, which is rather small for application. Another method is to apply an actuator for displacing the relative position of two parallel electrode plates and adjusting the overlapping area for changing the capacitance. The tuning range is still limited to the displacement of the actuator and electrode plates and unsatisfied for the needs of higher capacitance to area ratios.

Tunable inductors are further difficult to be made. As disclosed in U.S. Pat. No. 6,184,755, the inductance is adjusted by controlling the spacing of two inductive elements and changing their induction. However, the inductance change is not linear to the spacing change. Also, the inductive elements are not easy to be fabricated, and the inductances are not large enough.

U.S. Pat. No. 6,249,206 provides a laminated ferrite chip inductor array, in which the array is composed in that multiple layers of ferrite sheets printed with U-shaped patterns of internal conductors are piled in such a manner that the U-shaped patterns of the internal conductors on adjacent sheets are opposed as faced one another. However, the inductance to area ratio of the laminated inductor array is still limited and a higher inductance cannot be obtained.

### SUMMARY OF THE INVENTION

The object of the invention is to provide a tunable passive device, in which plurality of passive elements are stacked. In accompany with a tunable structure, the tunable passive device has advantages of higher inductance and larger tuning range.

A tunable passive device according to the invention includes a plurality of passive elements and at least a switch. The passive elements are stacked and spaced along a same direction, and connected with each other via the switch. By changing open/close conditions of the switch or switches and selecting specific passive elements that a current can pass, a responsive value of the tunable passive device is obtained.

The passive elements are capacitors or inductors. The switches for connecting the stacks are made by current micro electromechanical systems (MEMS) technologies. These are well-developed technologies. Therefore, the passive devices of the invention integrate current available elements and inventive constructions to improve the functions. The devices can be practically made by semiconductor fabrication process nowadays.

Furthermore, the tunable passive devices of the invention can be made of array element stacks. The tunable passive device includes a plurality of passive element array and at least a main switch. The passive element arrays are stacked and spaced along the same direction, and connected with each other via the main switch. By changing open/close conditions of the main switch or switches and selecting specific passive elements that a current can pass, a responsive value of the tunable passive device is obtained. Also, there are sub-switches in the passive element arrays for selectively changing the connections among passive elements. Therefore, multiple stages of responsive values can be adjusted.

### BRIEF DESCRIPTION OF THE DRAWINGS

The invention will become more fully understood from the detailed description given hereinbelow. However, this description is for purposes of illustration only, and thus is not limitative of the invention, wherein:

FIG. 1 is a first embodiment of the invention applied to a tunable inductor;

FIGS. 1A and 1B are functional views of a tunable inductor of the invention;

FIG. 2 is a second embodiment of the invention applied to a tunable inductor;

FIG. 2A is a functional view of a tunable inductor of the invention;

FIG. 3 is a third embodiment of the invention applied to a tunable capacitor; and

FIG. 4 is a fourth embodiment of the invention applied to a tunable passive array device.

### DETAILED DESCRIPTION OF THE INVENTION

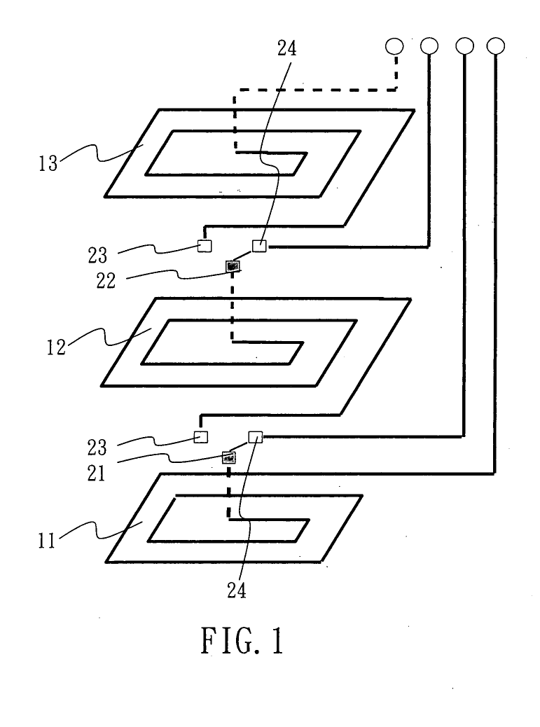

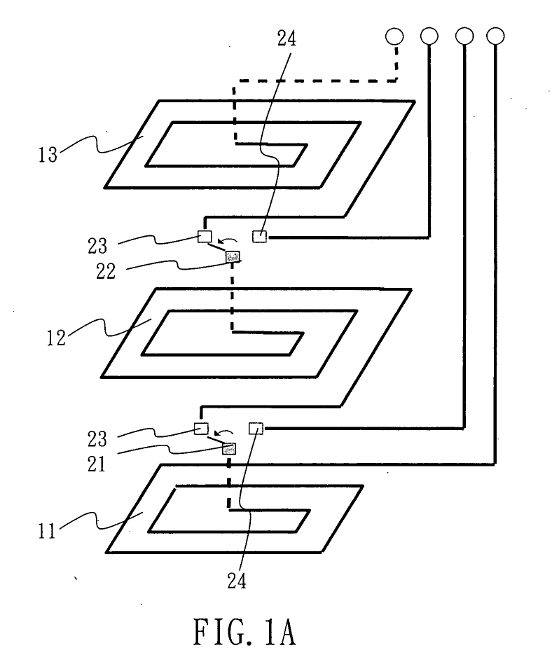

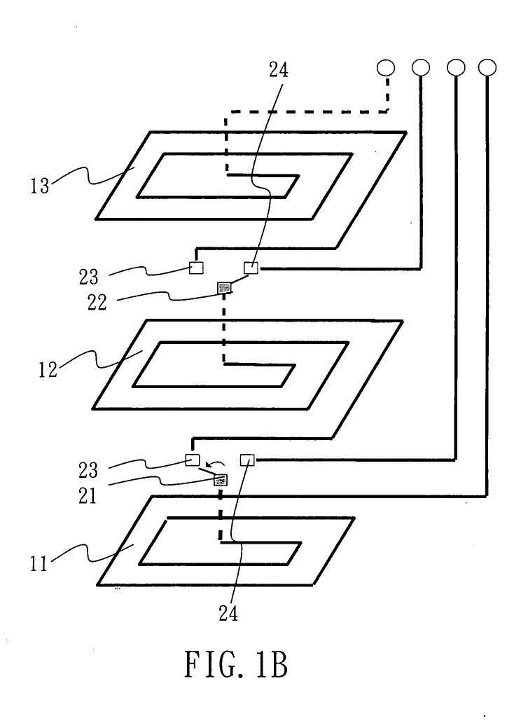

As shown in FIG. 1, a first embodiment of the invention is applied to a tunable inductor. The tunable inductor includes a first coil 11, a second coil 12, a third coil 13, a first switch 21 and a second switch 22. The second coil 12 is stacked on top of the first coil 11 and serially connected through the first switch 21. The third coil 13 is stacked on top of the second coil 12 and serially connected through the second switch 22. Each of the switches 21 and 22 has selectable first contact 23 and second contact 24. When the first contact 23 is connected, it is in a “close” condition. When the second contact 24 is connected, it is in an “open” condition. The invention adjusts the inductance by the switch conditions. As shown in FIG. 1, the switches 21 and 22 are all in “open” conditions so that current flow only through the first coil 11 and gets a single coil inductance.

The inductance of the first, second and third coils 11, 12, 13 can be the same. While, through changing the connection conditions of the switches 21 and 22, different inductance can be obtained. For example, as shown in FIG. 1A, the first and second switches 21 and 22 are all in “close” conditions so that the first, second and third coils 11, 12 and 13 are connected serially through contacts 23 of the switches 21 and 22, and three times of inductance is obtained.

Then, in FIG. 1B, the first switch 21 is in “close” condition, while the second switch 22 is in “open” condition. A current can pass the first coil 11 and the second coil 12 and get two times of inductance of a single coil. Similarly, when the first switch 21 is in “open” condition, and the second switch 22 is in “close” condition, a current can pass the second coil 12 and the third coil 13 and get the same result of two times of inductance.

Further, because coil inductance has a direction corresponding to the clockwise or counterclockwise of the current passing the coil. In the aforesaid first embodiment, the coils 11, 12 and 13 are applied with the same direction of current. However, any of the coils can be arranged to connect to different direction of current, and the inductance can be finely tuned by the mutual induction.

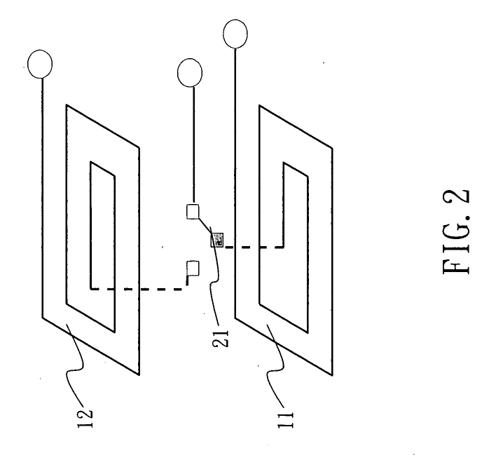

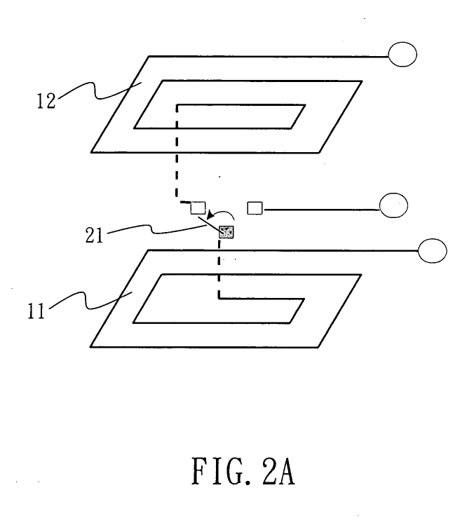

As shown in FIG. 2, a second embodiment of the invention is applied to a tunable inductor. The inductor includes a first coil 11, a second coil 12 and a switch 21. The second coil 12 is stacked on top of the first coil 11 and serially connected through the switch 21. Through wiring arrangement, a current can pass the first coil 11 counterclockwise; while, the current can pass the second coil 12 clockwise. Supposed the first coil 11 has an inductance L1; the second coil 12 has an inductance L2; and L1>L2. However, in FIG. 2, the switch 21 is in “open” condition, a current only passes the first coil 11 and gets a single coil inductance L1.

The function of the tunable inductor is shown in FIG. 2A. The switch 21 is in “close” condition so that a current first passes the first coil 11 counterclockwise, then passes the second coil 12 clockwise. Because the current directions are different, the mutual inductance M of the two coils is negative. Therefore, the total inductance is L1+L2−M. The tunable inductor is thus tuned by changing a part of the current directions of the coils.

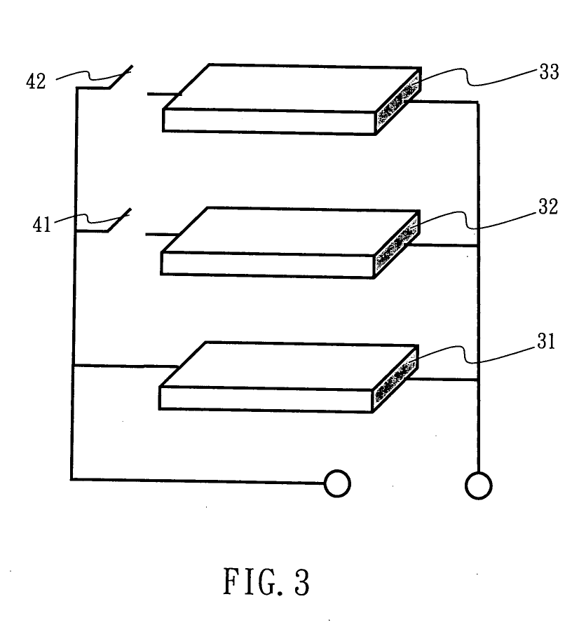

FIG. 3 is a third embodiment of the invention applied to a tunable capacitor. The tunable capacitor includes a first laminated capacitor 31, a second laminated capacitor 32, a third laminated capacitor 33, a first switch 41 and a second switch 32. The second laminated capacitor 32 is connected in parallel to the first laminated capacitor 31 through the first switch 41. The third laminated capacitor 33 is connected in parallel to the second laminated capacitor 32 through the second switch 42. By changing the connection conditions of the switches 41 and 42, different numbers of laminated capacitors are connected to provide different capacitance outputs.

As described above, the tunable passive elements (capacitors or inductors) are connected in parallel or in serial so as to get several times of capacitance or inductance. By changing the connection or switch conditions, the correspondent capacitance or inductance can be changed.

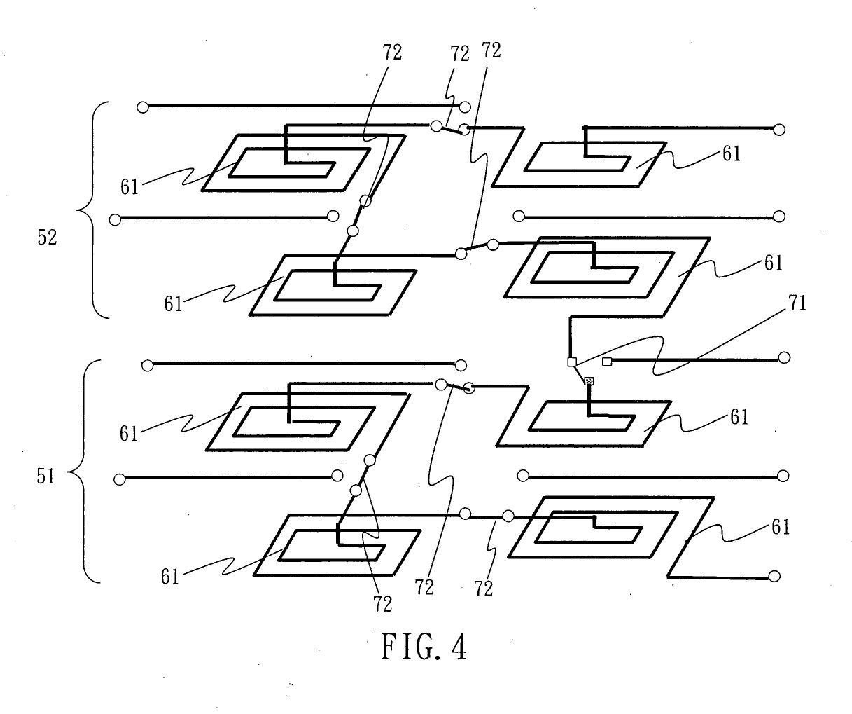

Further, the tunable passive elements can be connected through element arrays so as to achieve a larger range of tuning. FIG. 4 shows a fourth embodiment of the invention applied to a tunable inductor having a plurality of inductor arrays. The tunable inductor includes a first inductor array 51, a second inductor array 52 and a main switch 71 connected between the two arrays. The first inductor array 51 is composed of four coils 61 on a same plane. The second inductor array 52 is also composed of four coils 61 on a same plane and stacked on top of the first inductor array 51. The second inductor 52 connects serially to the first inductor array 51 through the main switch 71 and forms a tunable inductor.

Each of the inductor arrays 51 and 52 includes several sub-switches for multiple stages of inductance tuning. As shown in FIG. 4, each of the first inductor array 51 and the second inductor array 52 includes first, second and third coils 61 and three sub-switches 72. The first, second and third coils 61 are serially connected by the three sub-switches 72. By controlling the connection conditions of the sub-switches 72, the inductances of the first and second inductor arrays 51 and 52 are adjustable. Further, by controlling the connection condition of the main switch 71, the total inductance of the first and second inductor arrays 51 and 52 is tuned.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A tunable passive device, comprising:
a plurality of passive elements, stacked and spaced in a direction, for receiving a current and generating an induction; and
at least a switch, electrically connected with said passive elements, for tuning a total induction of said passive elements by changing open/close conditions of said switch and changing connection conditions of said passive elements.

2. The tunable passive device according to claim 1 wherein said passive elements are inductors.

3. The tunable passive device according to claim 2 wherein said inductors are connected in parallel.

4. The tunable passive device according to claim 2 wherein said inductors are connected serially.

5. The tunable passive device according to claim 2 wherein changing open/close conditions of said switch is to select a path of current flowing through said passive elements.

6. The tunable passive device according to claim 2 wherein changing open/close conditions of said switch is to control the direction of said current.

7. The tunable passive device according to claim 2 wherein said inductors are coils.

8. The tunable passive device according to claim 7 wherein direction of current flowing through said coils is chosen from a group of clockwise, counterclockwise and both.

9. The tunable passive device according to claim 1 wherein said passive elements are capacitors.

10. The tunable passive device according to claim 9 wherein said capacitors are connected in parallel via said switches.

11. The tunable passive device according to claim 9 wherein said capacitors are connected serially via said switches.

12. The tunable passive device according to claim 9 wherein said capacitors are laminated capacitors.

13. A tunable passive device, comprising:
a plurality of passive element arrays each comprises a plurality of passive elements, stacked and spaced in a direction, for receiving a current and generating an induction; and
at least a main switch, electrically connected with said passive element arrays, for tuning a total induction of said passive element arrays by changing open/close conditions of said main switch and changing connection conditions of said passive element arrays.

14. The tunable passive device according to claim 13 further comprises a plurality of sub-switches for electrically connecting a plurality of said passive elements.

15. The tunable passive device according to claim 14 wherein said sub-switches is to change open/close conditions and change connection of said passive elements.

16. The tunable passive device according to claim 13 wherein said passive element arrays are inductors.

17. The tunable passive device according to claim 16 wherein said inductors are connected in parallel.

18. The tunable passive device according to claim 16 wherein said inductors are connected serially.

19. The tunable passive device according to claim 16 wherein changing open/close conditions of said switch is to select a path of current flowing through said passive elements.

20. The tunable passive device according to claim 16 wherein changing open/close conditions of said switch is to control the direction of said current.

21. The tunable passive device according to claim 16 wherein said inductors are coils.

22. The tunable passive device according to claim 21 wherein direction of current flowing through said coils is chosen from a group of clockwise, counterclockwise and both.

23. The tunable passive device according to claim 13 wherein said passive elements are capacitors.

24. The tunable passive device according to claim 23 wherein said capacitors are connected in parallel via said switches.

25. The tunable passive device according to claim 23 wherein said capacitors are connected serially via said switches.

26. The tunable passive device according to claim 23 wherein said capacitors are laminated capacitors.
